(19) United States
(12) Patent Application Publication
(10) Pub. No.: US 2007/0210419 A1
(43) Pub. Date: Sep. 13, 2007

(54) Electrostatic discharge protection device in integrated circuit

(76) Inventors: Masakatsu Nawate, Toyama (JP); Manabu Imahashi, Osaka (JP)

Correspondence Address: MCDERMOTT WILL & EMERY LLP, 600 13TH STREET, NW, WASHINGTON, DC, 20005-3096, US

(21) Appl. No.: 11/715,406

(22) Filed: Mar. 8, 2007

(30) Foreign Application Priority Data
Mar. 9, 2006 (JP) 2006-063952

(51) Int. Cl. H01L 27/082; H01L 27/102

(52) U.S. Cl. 257/565

(57) ABSTRACT

An electrostatic discharge protection device of a semiconductor integrated circuit, comprising a first diffusion layer that is a diffusion layer of a second conductivity type provided on a semiconductor substrate of a first conductivity type and serves as a collector, a second diffusion layer that is a diffusion layer of the first conductivity type provided in the first diffusion layer and serves as a base, a third diffusion layer that is a diffusion layer of the second conductivity type provided in the second diffusion layer and serves as an emitter, a collector contact region provided in the first diffusion layer, a fourth diffusion layer that is a diffusion layer of the second conductivity type provided in the first diffusion layer in a downward region of the collector contact region in a substrate-thickness direction, wherein the fourth diffusion layer is formed shallower in a depth than that of the first diffusion layer in the substrate-thickness direction, deeper in a depth than that of the second diffusion layer in the substrate-thickness direction and with a high density than that of the first diffusion layer, and an insulation film formed on a surface of the first diffusion layer between the second diffusion layer and the collector contact region and serving as a field, wherein the fourth diffusion layer is extended up until a region below the insulation film.

### BACKGROUND OF THE INVENTION

1. Field of the Invention

The present invention relates to an electrostatic discharge protection device mainly in a bipolar or Bi-CMOS process.

2. Description of the Related Art

In order to protect an internal circuit in a semiconductor integrated circuit from breakdown due to static electricity charged in a human body, machine and the like, a semiconductor integrated circuit is conventionally provided with ESD (Electrostatic Discharge) protection circuit. The ESD protection circuit is described referring to FIG. 4.

In the ESD protection circuit, a highest-potential-side diode 15 and a lowest-potential-side diode 16 are connected to an input/output terminal 12 of the semiconductor integrated circuit, and an ESD protection device 18 of NPN-transistor type is connected between a highest-potential terminal 13 and a lowest-potential terminal 14. When the lowest-potential terminal 14 is grounded and a plus surge is applied to the input/output terminal 12, the highest-potential-side diode 15 is conducted, then, a collector and a base of the ESD protection device 18 of the NPN transistor type are broken down, and a current thereby flows through a resistor 19 between the base and emitter. As a result, the ESD protection device 18 is also conducted. Accordingly, a surge current flows through such a route as input/output terminal 12→highest-potential-side diode 15→ESD protection device 18→lowest-potential terminal 14. It is necessary to design the ESD protection device 18 constituted as just described in such a manner that the surge current flows through the ESD protection circuit prior to an internal circuit 11.

Next, an operation of the ESD protection device 18 under the surge phenomenon is described referring to the VI characteristic of the collector shown in FIG. 5. Here, as an example of the operation of the ESD protection device 18, the snap-back characteristic of the NPN transistor, which is generally known, is described. When the surge is applied to the collector of the NPN transistor, the NPN transistor breaks down at a transistor OFF withstand voltage BV_{cbo}, and the NPN transistor start its operation through a breakdown current thereby generated (snap-back start voltage: Vt1). When the NPN transistor starts its operation, a conductivity modulation is generated between the collector and emitter, and then a resistance between the collector and emitter is descended. At the time, a voltage between the collector and emitter of the transistor is retained at a voltage determined by the product of the resistance between the collector and emitter, and collector current (retained voltage: Vh). The current continues to flow between the collector and emitter because of the operation of the transistor thus described, and the NPN transistor reaches secondary breakdown down when heat generated in the silicon determined by the product of the current and the voltage of the collector reaches 1500° C. (melting point of silicon) (secondary breakdown current: It2).

When the ESD protection device is designed in the NPN transistor executing the such like snap-back operation, the retained voltage Vh is necessary to be secured of at least a maximum operation voltage of the internal circuit. It is because an excessive amount of current supply flows from the power supply of the internal circuit to the ESD protection device of the NPN transistor type and thereby the secondary breakdown of the ESD protection device of the NPY transistor type is caused due to the heat generated therein if the retained voltage Vh is reduced to be lower than the maximum operation voltage of the internal circuit. Therefore, the retained voltage Vh has to be at least the maximum operation voltage, and it is necessary to have a constitution for making the retained voltage Vh to a higher voltage.

One of conventional examples of the technology for providing a high voltage to the retained voltage Vh in the ESD protection device in which the NPN transistor is utilized is a first conventional technology recited in No. 2002-542628 of the Japanese Patent Application National Publication. The first conventional technology is described below referring to FIG. 6. In the first conventional technology, an N⁺⁺ layer 107, which is a collector contact region, is surround by an N-type epitaxial layer 102 so that a resistance is formed by the N-type epitaxial layer 102 in a collector region between a high-density N-type sink layer 103 and the N⁺⁺ layer 107. The current flowing through the collector region at operation of the transistor follows such a route as N⁺⁺ layer 107→N-type epitaxial layer 102→high-density N-type sink layer 103→N-type buried layer 110, and further it flows in such a route as N-type epitaxial layer 102—P⁻ layer 104→N⁺⁺ layer 106 in the vertical direction from the collector toward the emitter. When a distance X′ in the horizontal direction between the high-density N-type sink layer 103 and the N⁺⁺ layer 107 is increased, a value of the resistance formed by the N-type epitaxial layer 102 is increased so that the retained voltage Vh is made to a higher voltage.

However, an ESD capability becomes low in the first conventional technology because a depletion layer extending from the P⁻ layer 104 easily reaches the N⁺⁺ layer 107 due to the Kirk effect (base push-out effect) when a large amount of collector current flow is generated since there is only the N-type epitaxial layer 102 having a low density between the P⁻ layer 104 and the N⁺⁺ layer 107. When the depletion layer reaches the N⁺⁺ layer 107 due to the Kirk effect, an electric field immediately below the N⁺⁺ layer 107 is intensified, and a large amount of current flow is thereby generated, which results in the secondary breakdown.

A second conventional technology recited in No. 2004-312549 of the Japanese Patent Applications Laid-Open aims to solve the problem of the first conventional technology (low ESD capability). The second conventional technology is described below referring to FIG. 7. In the second conventional technology, a high-density N-type sink layer 203, which is deeper than an N⁻ layer 202a, is formed in an N⁺⁺ region 207a that is a collector contact region. Through forming the high-density N-type sink layer 203, the Kirk effect is generated in the state where the collector current is high, and an depletion layer extending from a P⁺ layer 205 reaches a P⁻ substrate 201, therefore the P⁺ layer 205, N⁻ layer 202a and P⁻ substrate 201 apparently serve as base layers. As a result, the NPN transistor, in which the high-density N-type sink layer 203 serves as the collector, the P⁺ layer 205, N⁻ layer 202a and P⁻ substrate 201 serve as the base layers, and the N⁺⁺ layer 206 serves as the emitter layer, is operated. At the time, the electric field moving by the Kirk effect is concentrated on joint end of the high-density N-type sink layer 203 and the P⁻ substrate 201. Therefore, the heat is generated at a point deeper than the N⁺⁺ region 207a, and the ESD capability can be thereby improved.

In the constitution according to the second conventional technology described above, the retained voltage Vh is determined by the product of the current flow in operating the transistor and the resistance between the collector and emitter. Therefore, separation of the high-density N-type sink layer 203 and the P⁺ layer 205 are further increased in the constitution according to the second conventional technology in order to form the resistor in the N⁻ layer 202a. As a result, the transistor OFF withstand voltage BV_{cbo} and the retained voltage Vh can be increased as shown in FIG. 8.

However, the increase of the retained voltage Vh is still insufficient, and the protection device can be used only in a limited voltage range. Further, the amount of heat generated in joint part of the collector-base is increased, which lowers the secondary breakdown current It2. FIG. 8 shows variations of the transistor OFF withstand voltage BV_{cbo}, retained voltage Vh and secondary breakdown current It2 to the separation between the high-density N-type sink layer 203 and the P⁺ layer 205.

Thus, in the constitution according to the second conventional technology proposed in order to obtain the sufficient retained voltage Vh, it is necessary to provide another constitution for improving the retained voltage Vh because the merit of the second conventional technology is lost.

In the second conventional technology, the resistance formed in the horizontal direction by the high-density N-type sink layer 203 is defined by a degree of diffusion of the high-density N-type sink layer 203 extended in the horizontal direction because the high-density N-type sink layer 203 is formed in the same section as that of the N⁺⁺ region 207a, however, the value of the resistance thus defined is not sufficient. Therefore, the retained voltage of the ESD protection device of the NPN-transistor type may be lower than the maximum operation voltage in the integrated circuit having a high voltage resistance, which unfavorably results in the secondary breakdown of the protection device itself.

### SUMMARY OF THE INVENTION

Therefore, a main object of the present invention is to provide an ESD protection device that can be prevented from secondary breakdown in such a manner that a retained voltage Vh is made to a higher voltage without depending on a value of a maximum operation voltage of an internal circuit.

In order to achieve the foregoing object, an electrostatic discharge protection device according to the present invention is an electrostatic discharge protection device of a semiconductor integrated circuit consisting of a bipolar transistor, comprising:

a semiconductor substrate of a first conductivity type;

a first diffusion layer that is a diffusion layer of a second conductivity type provided on the semiconductor substrate and serves as a collector;

a second diffusion layer that is a diffusion layer of the first conductivity type provided in the first diffusion layer and serves as a base;

a third diffusion layer that is a diffusion layer of the second conductivity type provided in the second diffusion layer and serves as an emitter;

a collector contact region provided in the first diffusion layer;

a fourth diffusion layer that is a diffusion layer of the second conductivity type provided in the first diffusion layer in a downward region in a substrate-thickness direction of the collector contact region, and is formed shallower than that of the first diffusion layer in the substrate-thickness direction, deeper than that of the second diffusion layer in the substrate-thickness direction and with a higher density than that of the first diffusion layer; and

an insulation film formed on a surface of the first diffusion layer between the second diffusion layer and the collector contact region so as to serve as a field, wherein
the fourth diffusion layer is extended through a region below the insulation film.

The first conductivity type and the second conductivity type respectively refer to one of p type and n type of the semiconductor. When the first conductivity type is the p type, the second conductivity type is the n type. Adversely, when the first conductivity type is the n type, the second conductivity type is the p type.

According to the foregoing constitution, by extending the fourth diffusion layer from the collector contact region through the region below the insulation film, a built-in resistor is formed in the fourth diffusion layer so as to generate voltage drop. As a result, the retained voltage Vh is made to a higher voltage in comparison to the case where the fourth diffusion layer is not provided below the insulation film.

In the foregoing constitution, it is preferable that the collector contact region and the emitter are connected to an output terminal of the semiconductor integrated circuit, and the collector contact region is connected to an output terminal having a potential higher than that of the output terminal connected to the emitter. Further, it is more preferable that the collector contact region is connected to a highest-potential terminal of the semiconductor integrated circuit, and the emitter is connected to a lowest-potential terminal of the semiconductor integrated circuit.

In the foregoing constitution, an extended dimension of the fourth diffusion layer extending from a border between the collector contact layer and the insulation film to below the insulation film is preferable to be at least 10 μm. The region of the fourth diffusion layer below the insulation film forms the built-in resistor, and the built-in resistor is serially connected to the collector. The built-in resistor conforms to the extended width of the fourth diffusion layer region below the insulation film, and the tilt of the snap-back characteristic is increased as the extended width is increased. According to an experiment, the extended width is desirably at least 10 μm in order to maintain the retained voltage Vh to be at least 40 V.

In the foregoing constitution, it is preferable that a fifth diffusion layer of the first conductivity type is formed in at least a part of the fourth diffusion layer below the insulation film. By doing this, a pinch resistor is formed in the region of the fourth diffusion layer below the fifth diffusion layer, and the pinch resistor is serially connected to the collector of the transistor. Even when it is desirable to obtain the higher retained voltage Vh, therefore, the retained voltage Vh can be further increased by changing the width of the fifth diffusion layer without any increase of the width of the fourth diffusion layer region itself (without any increase of a cell area). It is preferable that the fifth diffusion layer is provided in the fourth diffusion layer. Accordingly, a punch-through is formed through the fifth diffusion layer and the second diffusion layer, and the withstand voltage between the collector and base can be prevented from decreasing.

In the foregoing constitution, it is preferable that the second diffusion layer comprises a first diffusion region formed in the first diffusion layer and a second diffusion region having a density higher than that of the first diffusion region and formed in the first diffusion region.

According to the present invention, the fourth diffusion having the high density is extended from the collector contact region through the region below the insulation film. As a result, the retained voltage Vh can be made to a high voltage.

Further, the fifth diffusion layer of the first conductivity type is additionally formed in the fourth diffusion layer below the insulation film, so that the retained voltage Vh can be further increased without any increase of the area.

As described above, the technology according to the present invention is effectively applied to an ESD protection device of a semiconductor integrated circuit having a high withstand voltage.

### BRIEF DESCRIPTION OF THE DRAWINGS

These and other objects as well as advantages of the invention will become clear by the following description of preferred embodiments of the invention. A number of benefits not recited in this specification will come to the attention of those skilled in the art upon the implementation of the present invention.

FIG. 1 is a sectional view showing a structure of an electrostatic discharge protection device according to a preferred embodiment 1 of the present invention.

FIG. 2 is a characteristic curve chart of measurement data based on the TLP evaluation in which an effect of the preferred embodiment 1 was confirmed.

FIG. 3 is a sectional view showing a structure of an electrostatic discharge protection device according to a preferred embodiment 2 of the present invention.

FIG. 4 is a circuit diagram showing an example of an ESD protection circuit provided in a conventional integrated circuit.

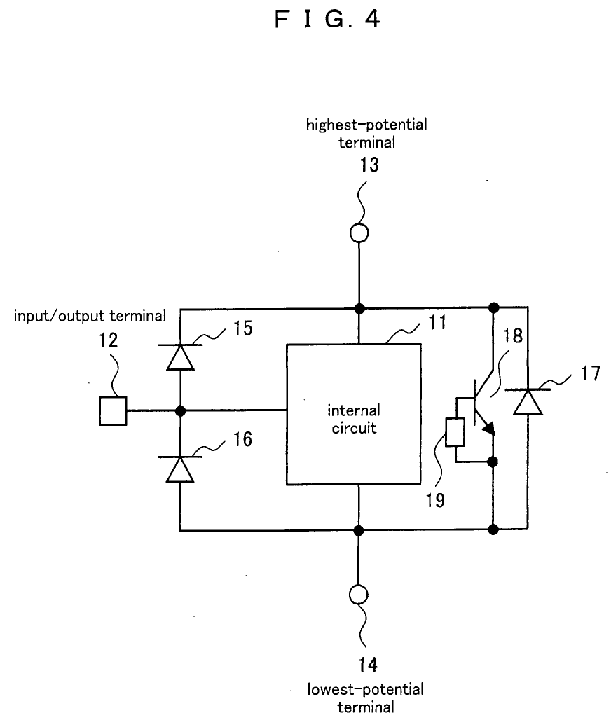

FIG. 5 is an illustration of the snap-back characteristic of an NPN transistor.

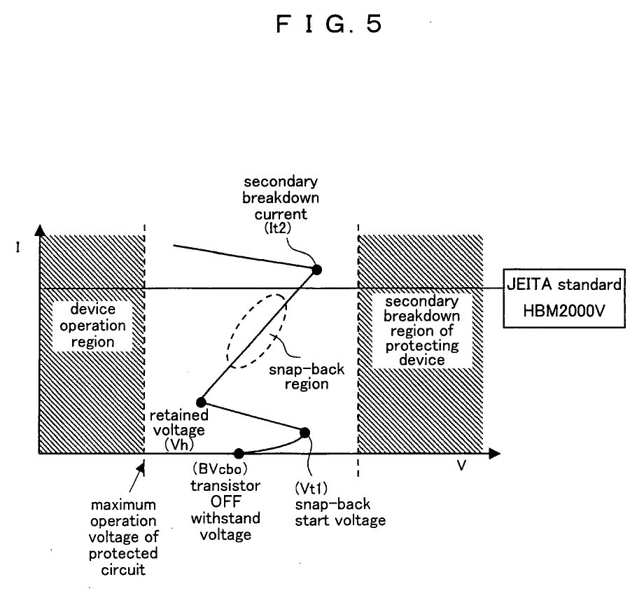

FIG. 6 is a sectional view showing a structure of an electrostatic discharge protection device recited in the Patent Literature 1.

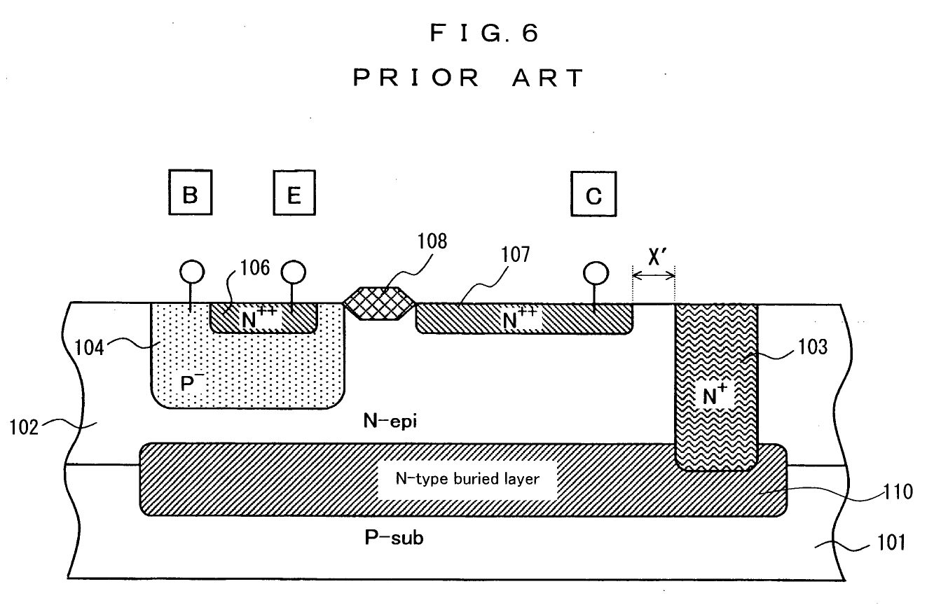

FIG. 7 is a sectional view showing a structure of an electrostatic discharge protection device recited in the Patent Literature 2.

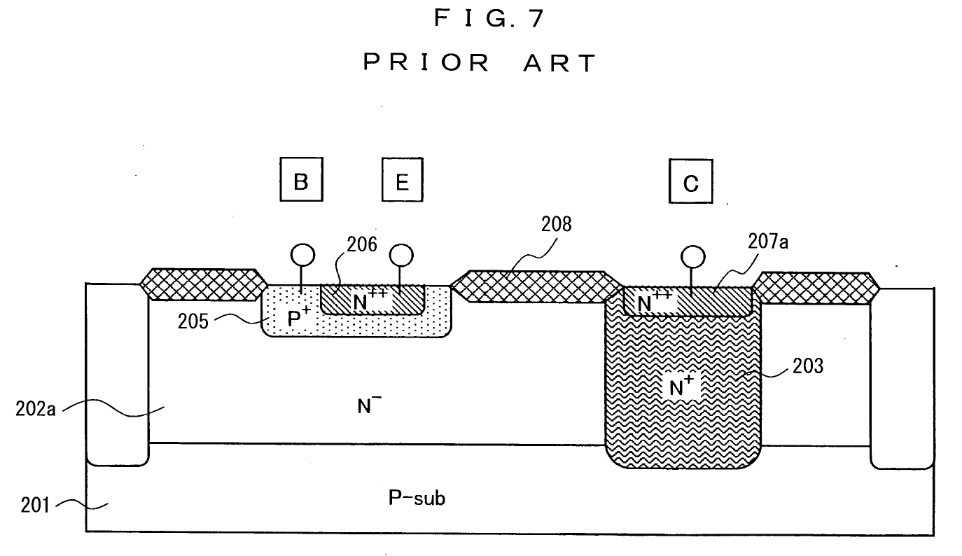

FIG. 8 is a characteristic curve chart shows how BV_{cbo}, retained voltage Vh, and secondary breakdown current It2 in relation to separation between a high-density N-type sink layer and a P⁻ layer recited in the Patent Literature 2 based on measurement data.

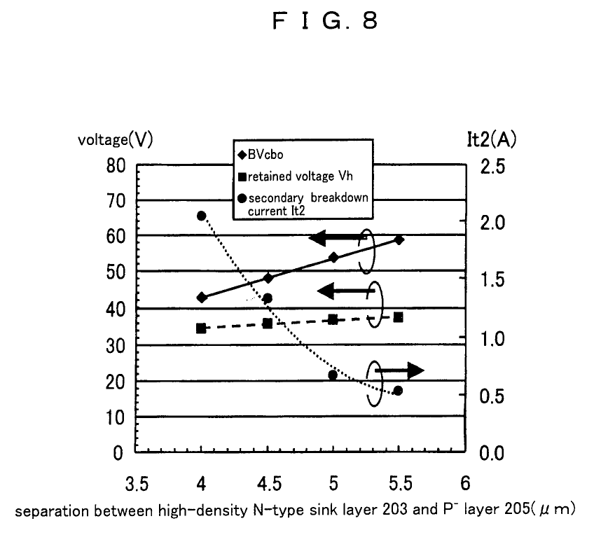

### DETAILED DESCRIPTION OF THE INVENTION

Hereinafter, preferred embodiments of the present invention are described referring to the drawings.

### Preferred Embodiment 1

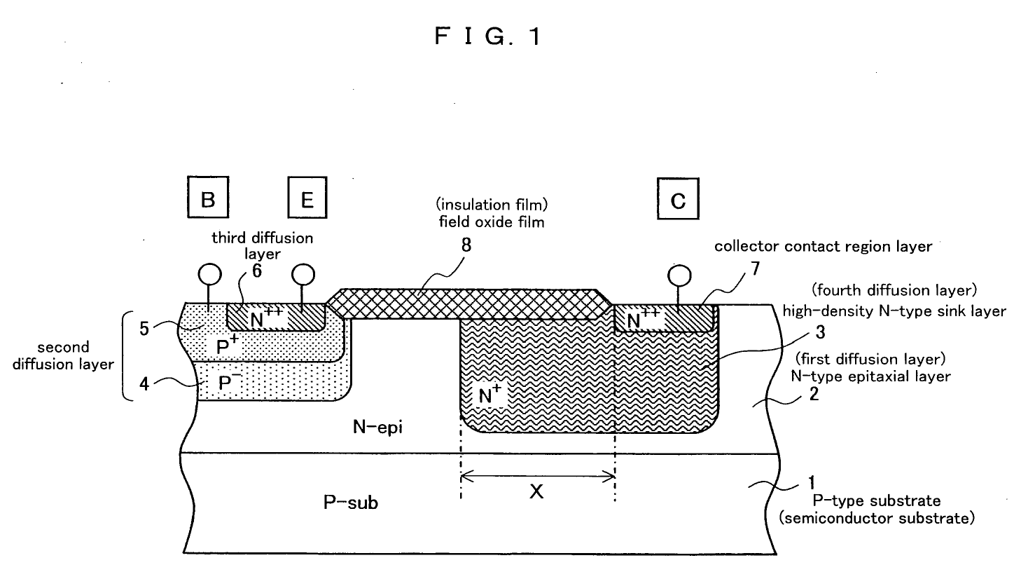

FIG. 1 is a sectional view showing a structure of an electrostatic discharge (ESD) protection device according to a preferred embodiment 1 of the present invention. The ESD protection device is suitable for providing an ESD protection to an internal circuit having a maximum operation voltage 40 V. As shown in FIG. 1, an N-type epitaxial layer 2 is formed on a P-type substrate 1 as a semiconductor substrate of a first conductivity type. The N-type epitaxial layer 2 is a first diffusion layer of a second conductivity type and serves as a collector. A high-density N-type sink layer 3 is formed from a surface of the N-type epitaxial layer 2 to inside thereof. The high-density N-type sink layer 3 is a fourth diffusion layer of the second conductivity type and serves as a collector layer. The high-density N-type sink layer 3 is formed with a density higher than that of the N-type epitaxial layer 2. A P⁻ layer 4 and a P⁺ layer 5 are formed in a region of the N-type epitaxial layer 2 distant from the high-density N-type sink layer 3 in a substrate-horizontal direction. The P⁺ layer 5 is provided in the surface part of the N-type epitaxial layer 2 (first diffusion layer), and the P⁻ layer 4 is provided on an inner side of the substrate of the P⁺ layer 5. The P⁺ layer 5 and the P⁻ layer 4 constitute a second diffusion layer of the first conductivity type. The P⁻ layer 4 constitutes a first diffusion region of the second diffusion layer, while the P⁺ layer 5 constitutes a second diffusion region of the second diffusion layer. The P⁺ layer 5 is the diffusion region having a density higher than that of the P⁻ layer 4. The second diffusion layer thus constituted serves as a base. A first N⁺⁺ layer 6 is formed in the P⁺ layer 5. The first N⁺⁺ layer 6 is formed in a surface region of the P⁺ layer 5 on the substrate surface side. The first N⁺⁺ layer 6 is a third diffusion layer of the second conductivity type and serves as an emitter. The high-density N-type sink layer 3 is formed shallower than that of the N-type epitaxial layer 2 in a substrate-thickness direction and deeper than that of the P⁻ layer 4 in the substrate-thickness direction. The high-density N-type sink layer 3 is formed with a density higher than that of the N-type epitaxial layer 2. A second N⁺⁺ layer 7 is formed in the high-density N-type sink layer 3, and the second N⁺⁺ layer 7 constitutes a collector contact region, in other words, the high-density N-type sink layer 3 is provided in the N-type epitaxial layer 2 located in a downward region of the second N⁺⁺ layer 7 in the substrate-thickness direction.

A field oxide film 8 is provided on the surface of the N-type epitaxial layer 2. The field oxide film 8 is provided between the second N⁺⁺ layer 7 and the P⁺ layer 5 and functions as an insulation film (field) between them. The second N⁺⁺ layer (collector contact region) 7 and the first N⁺⁺ layer (emitter) 6 are connected to an output terminal of a semiconductor integrated circuit to which the electrostatic discharge protection device is connected. The second N⁺⁺ layer 7 is connected to an output terminal having a higher potential than that of the output terminal of the semiconductor integrated circuit connected to the first N⁺⁺ layer 6. More desirably, the second N⁺⁺ layer 7 is connected to a highest-potential terminal of the semiconductor integrated circuit, while the first N⁺⁺ layer 6 is connected to a lowest-potential terminal of the semiconductor integrated circuit.

In the electrostatic discharge (ESD) protection device thus constituted, the field oxide film 8 is formed so as to overlap with the region of the high-density N-type sink layer 3 by at least a certain area. In other words, the high-density N-type sink layer 3 is formed in such a manner that extends from the second N⁺⁺ layer 7 through the region below the field oxide film 8.

A more detailed aspect is given below. A thickness of the N-type epitaxial layer 2 is approximately 4.2 μm. The high-density N-type sink layer 3 is formed from the surface of the N-type epitaxial layer 2 up until a position in a depth of approximately 3.5 μm, and a peak density thereof is approximately 3×10¹⁷/cm³. A depth of the P⁻ layer 4 is approximately 2.0 μm from the surface of the N-type epitaxial layer 2, and a peak density thereof is approximately 6×10¹⁶/cm³. A depth of the P⁺ layer 5 is approximately 0.5 μm, and a peak density thereof is approximately 2.0×10¹⁷/cm³. A depth of the first N⁺⁺ layer 6 is approximately 0.2 μm, and a peak density thereof is approximately 2.5×10²⁰/cm³. A depth of the second N⁺⁺ layer 7 is approximately 0.2 μm, and a peak density thereof is approximately 2.5×10²⁰/cm³. A region width X where the high-density N-type sink layer 3 and the field oxide film 8 overlap with each other (extended dimension of the high-density N-type sink layer 3 expanding from a border between the second N⁺⁺ layer 7 and the field oxide film 8 up until below the field oxide film 8) is 10-40 μm.

An operation of the transistor having the foregoing structure is described below. First, when a surge is applied to the collector, breakdown is caused between the P⁻ layer 4 and the high-density N-type sink layer 3 in the case where a withstand voltage determined by the separation between them exceeds the predetermined value. Based on a breakdown current thereby generated, the operation of the NPN transistor constituting the electrostatic discharge protection device according to the present preferred embodiment is started, and the current flows from the collector to the emitter. At the time, the current flow by the transistor operation passes from the second N⁺⁺ layer 7 through the region of the high-density N-type sink layer 3 below the field oxide film 8, and further flows to the emitter via the route of N-type epitaxial layer 2→P⁻ layer 4→P⁺ layer 5→first N⁺⁺ layer 6.

Here, a built-in resistor having a sufficiently large value is formed in the high-density N-type sink layer 3 through making the region width X larger, which generates voltage drop. Therefore, the retained voltage Vh is made to be a higher voltage in comparison to the case where the high-density N-type sink layer 3 is not provided below the field oxide film 8.

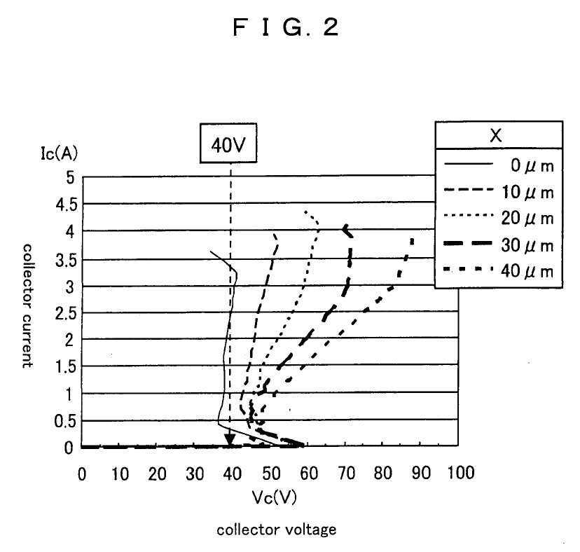

In order to confirm the effect of the present invention based on the recognition that the retained voltage Vh is improved as the region width X is increased, the region width X was changed under a state where the separation between the high-density N-type sink layer 3 and the P⁻ layer 4 shown in FIG. 1 was maintained at a certain level, and the change of the retained voltage Vh was simulated based on an actual measurement. The measurement and the simulation were implemented by means of the TLP (Transmission Line Pulse). The result is shown in FIG. 2. FIG. 2 shows the snap-back characteristic in the different region widths X, based on an assumption that the horizontal axis denotes the collector voltage and the vertical axis denotes the collector current.

As shown in FIG. 2, when the region width X is 0 μm, the retained voltage Vh is reduced to at most 40 V. On the contrary, when the region width X is at least 10 μm, the retained voltage Vh holds at least 40 V because the built-in resistor formed in accordance with the region width X is serially connected to the collector of the NPN transistor. Focusing on the transistor operation region (0.5 A-3.5 A) after the retained voltage Vh shown in FIG. 2, the tilt of the snap-back characteristic is increased as the region width X is increased.

As described above, a higher voltage of the retained voltage Vh is achieved according to the present invention, and the ESD protection device of the NPN transistor free of any restriction from a voltage range can be provided in the integrated circuit having the high voltage resistance.

### Second Preferred Embodiment 2

In the preferred embodiment 1, improvement of the retained voltage Vh is tried by expanding the region width X of the high-density N-type sink layer 3 below the field oxide film 8. However, it is necessary to set the region width X to at least 10 μm in order to be secured of the retain voltage Vh of at least 40 V as shown in FIG. 2.

In the case where use of the ESD protection device is desired in the range of higher voltages, it is necessary to further broaden the region width X. When use of the ESD protection device is tried in the region of the power-supply voltage of 50V, for example, it is necessary for the region width X to be at least 50 μm, which means that the cell area of the ESD protection device is increased to at least 50 μm in the horizontal direction. Therefore, the area of the ESD protection device occupied in the entire area of the chip is increased, and the chip size may be unfavorably increased in the constitution according to the preferred embodiment 1.

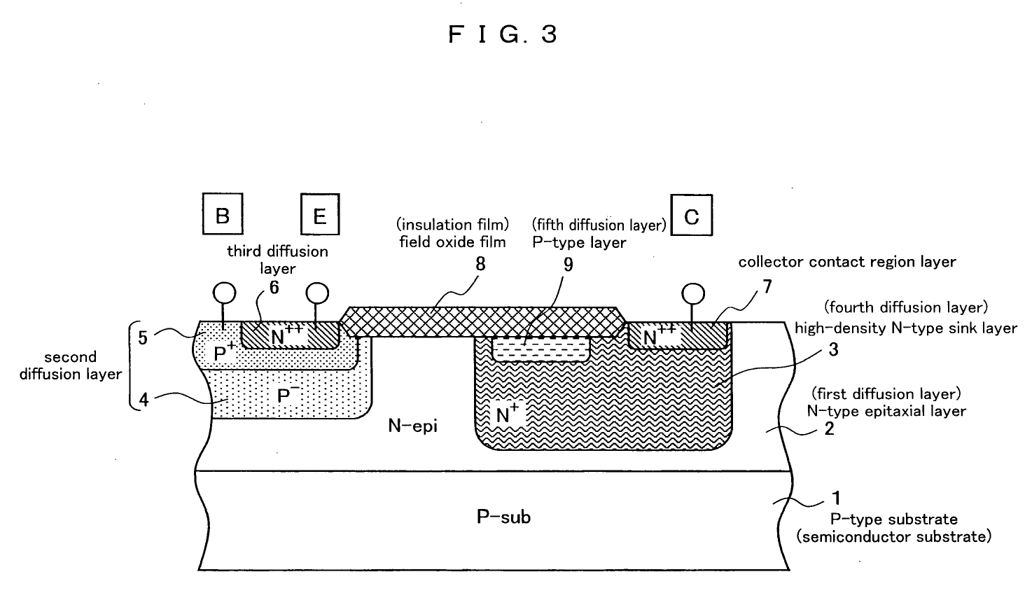

A structure according to a preferred embodiment 2 of the present invention, that can dispel such anxiety, is described referring to FIG. 3. This is the structure for making the resistance formed in the high-density N-type sink layer 3 below the field oxide film 8 to be much higher value. A P-type layer 9 is formed on the surface in at least a partial region of the high-density N-type sink layer 3 below the field oxide film. The P-type layer 9 constitutes a fifth diffusion layer of the first conductivity type. As shown in FIG. 3, it is preferable that the P-type 9 is arranged in the high-density N-type sink layer 3 below the field oxide film 8. By doing this, a punch-through is formed with the P-type layer 9 and the P⁻ layer 4, and the voltage resistance between the collector and base can be prevented from decreasing.

According to the foregoing constitution, a pinch resistor is formed in the region of the high-density N-type sink layer 3 below the P-type layer 9. The pinch resistor is serially connected to the collector of the transistor, and the retained voltage Vh is thereby further increased. As a result, the enlargement of the region of the high-density N-type sink layer 3 can be reduced to a minimum level, and the cell area can be thereby prevented from increasing.

In the preferred embodiments, the polarities (conductivity types) of the diffusion layers may be reversed. Further, the two diffusion layers, which are the P⁻ layer 4 and the P⁺ layer 5, constitute the base, however, the effect of the present invention can be still exerted in the case where a single diffusion layer is alternately used.

While the preferred embodiments of this invention has been described in detail, it will be understood that various modifications may be made therein, and it is intended to cover in the appended claims all such modifications as fall within the true spirit and scope of this invention.

What is claimed is:

1. An electrostatic discharge protection device of a semiconductor integrated circuit comprising a bipolar transistor, comprising:
a semiconductor substrate of a first conductivity type;
a first diffusion layer that is a diffusion layer of a second conductivity type provided on the semiconductor substrate and serves as a collector;
a second diffusion layer that is a diffusion layer of the first conductivity type provided in the first diffusion layer and serves as a base;
a third diffusion layer that is a diffusion layer of the second conductivity type provided in the second diffusion layer and serves as an emitter;
a collector contact region provided in the first diffusion layer;
a fourth diffusion layer that is a diffusion layer of the second conductivity type provided in the first diffusion layer in a downward region of the collector contact region in a substrate-thickness direction, wherein the fourth diffusion layer is formed shallower in a depth than that of the first diffusion layer in the substrate-thickness direction, deeper in a depth than that of the second diffusion layer in the substrate-thickness direction and with a higher density than that of the first diffusion layer; and
an insulation film formed on a surface of the first diffusion layer between the second diffusion layer and the collector contact region and serving as a field, wherein
the fourth diffusion layer is extended up until a region below the insulation film.

2. The electrostatic discharge protection device as claimed in claim 1, wherein
the collector contact region and the emitter are connected to an output terminal of the semiconductor integrated circuit, and the collector contact region is connected to an output terminal having a potential higher than that of the output terminal connected to the emitter.

3. The electrostatic discharge protection device as claimed in claim 1, wherein
the collector contact region is connected to a highest-potential terminal of the semiconductor integrated circuit, and the emitter is connected to a lowest-potential terminal of the semiconductor integrated circuit.

4. The electrostatic discharge protection device as claimed in claim 1, wherein
an extended dimension of the fourth diffusion layer extending from a border between the collector contact layer and the insulation film to below the insulation film is at least 10 μm.

5. The electrostatic discharge protection device as claimed in claim 1, wherein
a fifth diffusion layer of the first conductivity type is formed in at least a part of the fourth diffusion layer below the insulation film.

6. The electrostatic discharge protection device as claimed in claim 5, wherein
the fifth diffusion layer is arranged in the fourth diffusion layer.

7. The electrostatic discharge protection device as claimed in claim 1, wherein
the second diffusion layer comprises a first diffusion region formed in the first diffusion layer and a second diffusion region having a density higher than that of the first diffusion region formed in the first diffusion region.
